(19) United States
(12) Patent Application Publication
(10) Pub. No.: US 2026/0304985 A1
(43) Pub. Date: Oct. 1, 2026

(54) IMAGING MODULE AND IMAGING DEVICE

(71) Applicant: Samsung Electronics Co., Ltd., Suwon-si (KR)

(72) Inventor: Yuji Nishida, Yokohama (JP)

(21) Appl. No.: 19/631,089

(22) Filed: Mar. 27, 2026

(30) Foreign Application Priority Data
Mar. 31, 2025 (JP) 2025-058322
Jul. 14, 2025 (KR) 10-2025-0094757

(51) Int. Cl. H10F 39/00; G02B 7/02; G02B 7/04

(52) U.S. Cl. CPC H10F 39/8063; G02B 7/021; G02B 7/04; H10F 39/811

(57) ABSTRACT

An imaging module includes an imaging element having a light-receiving surface configured to receive light, and a cover covering the light-receiving surface of the imaging element. The cover is curved such that a light-transmitting surface of the cover that faces the light-receiving surface protrudes toward the imaging element and the imaging element is stacked on the light-transmitting surface of the cover, and the light-receiving surface is concavely curved toward an opposite side of the imaging element that is opposite to the light-transmitting surface.

### CROSS-REFERENCE TO RELATED APPLICATIONS

This application is based on and claims priority under 35 U.S.C. §119 to Japanese Patent Application No. 2025-058322, filed on March 31, 2025, in the Japan Patent Office, and Korean Patent Application No. 10-2025-0094757, filed on July 14, 2025, in the Korean Intellectual Property Office, the disclosures of which are incorporated by reference herein in their entireties.

### BACKGROUND

The disclosure relates to an imaging module and an imaging device.

### SUMMARY

The disclosure provides an imaging module including an imaging element, in which blurring of an image due to a light-receiving surface being misaligned with respect to the focus of a lens is prevented while suppressing the attachment of foreign matter to the light-receiving surface, and an imaging device including the imaging module.

In addition, the objective to be solved by the disclosure is not limited to the above-mentioned ones, and other objectives will be clearly understood by those skilled in the art from the description below.

According to an aspect of the disclosure, there is provided an imaging module including an imaging element having a light-receiving surface receiving light, and a cover covering the light-receiving surface of the imaging element, wherein the cover is curved such that a light-transmitting surface of the cover that faces the light-receiving surface protrudes toward the imaging element, and the imaging element is stacked on the light-transmitting surface of the cover, and the light-receiving surface is concavely curved toward an opposite side of the imaging element that is opposite to the light-transmitting surface.

According to another aspect of the disclosure, there is provided an imaging device including an imaging module including an imaging element having a light-receiving surface, and a cover covering the light-receiving surface of the imaging element, a lens configured to focus light on the light-receiving surface of the imaging element, and a retainer retaining the lens, wherein the cover is curved such that a light-transmitting surface of the cover that faces the light-receiving surface of the imaging element protrudes toward the imaging element, and the imaging element is stacked on the opposite surface of the cover, and the light-receiving surface is concavely curved toward a side opposite to the cover.

According to another aspect of the disclosure, there is provided an imaging device including an imaging module, a lens configured to focus light onto an imaging element of the imaging module, and a retainer retaining the lens, wherein the imaging module includes the imaging element having a light-receiving surface configured to receive light and having an electrode pad at a periphery of the light-receiving surface, a cover covering the light-receiving surface of the imaging element and having a wire connected to the electrode pad at a periphery of a light-transmitting surface of the cover that faces the light-receiving surface of the imaging element, and an interposer substrate which has a space formed therein in which at least the light-receiving surface of the imaging element is arranged, and which is connected to the wire of the cover, wherein the cover is curved such that the light-transmitting surface of the cover protrudes toward the imaging element, and wherein the imaging element is stacked on the light-transmitting surface of the cover, with an adhesive layer therebetween, and the light-receiving surface of the imaging element is concavely curved toward an opposite side of the imaging element that is opposite to the cover.

### BRIEF DESCRIPTION OF THE DRAWINGS

Embodiments will be more clearly understood from the following detailed description taken in conjunction with the accompanying drawings in which:

FIG. 1 is a cross-sectional view illustrating a structure of an imaging device according to an embodiment;

FIG. 2 is a plan view illustrating a structure of an imaging module according to an embodiment;

FIG. 3 is a cross-sectional view of the imaging module of FIG. 2;

FIG. 4 is an enlarged view showing region IV of FIG. 3;

FIG. 5 is a conceptual diagram illustrating the relationship between light incident on a lens and a light-receiving surface in an imaging device having a flat light-receiving surface;

FIGS. 6A and 6B are cross-sectional views illustrating a method of manufacturing an imaging module, according to an embodiment;

FIGS. 7A to 7C are a plan view and cross-sectional views illustrating a structure of an imaging module according to an embodiment;

FIGS. 8A to 8C are a plan view and cross-sectional views illustrating a structure of an imaging module according to an embodiment;

FIGS. 9A and 9B are cross-sectional views illustrating a structure of an imaging module according to an embodiment; and

FIGS. 10A and 10B are cross-sectional views illustrating a structure of an imaging module according to an embodiment.

### DETAILED DESCRIPTION OF THE EMBODIMENTS

Hereinafter, the disclosure will be described more fully with reference to the accompanying drawings, in which various embodiments are shown. The disclosure is not limited to the embodiments set forth herein and may be embodied in many different forms. For example, the disclosure may be implemented with various modifications within the scope of the gist thereof. It should also be emphasized that the disclosure provides details of alternative examples, but such listing of alternatives is not exhaustive. Furthermore, any consistency of detail between various examples should not be interpreted as requiring such detail. The same reference numerals are used for identical components in the drawings, and repeated descriptions may be omitted. Additionally, the drawings are intended to illustrate embodiments and do not represent actual sizes.

Throughout the specification, when a component is described as "including" a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

Items described in the singular herein may be provided in plural, as can be seen, for example, in the drawings. Thus, the description of a single item that is provided in plural should be understood to be applicable to the remaining plurality of items unless the context indicates otherwise.

It will be understood that when an element is referred to as being "connected" or "coupled" to or “on” another element, it can be directly connected or coupled to or on the other element or intervening elements may be present. In contrast, when an element is referred to as being "directly connected" or "directly coupled" to another element, or as “contacting” or “in contact with” another element (or using any form of the word “contact”), there are no intervening elements present at the point of contact. As the state of contact is binary (either in contact or not in contact), it will be appreciated that “contact” has the same scope as any use of “direct contact.”

As used herein, components described as being “electrically connected” are configured such that an electrical signal can be transferred from one component to the other (although such electrical signal may be attenuated in strength as it is transferred and may be selectively transferred). Moreover, components that are “directly electrically connected” form a common electrical node through electrical connections by one or more conductors, such as, for example, wires, pads, internal electrical lines, through vias, etc. As such, directly electrically connected components do not include components electrically connected through active elements, such as transistors or diodes.

Terms such as “same,” “equal,” etc. as used herein when referring to features such as orientation, layout, location, shapes, sizes, compositions, amounts, or other measures do not necessarily mean an exactly identical feature but is intended to encompass nearly identical features including typical variations that result from conventional manufacturing processes. The term “substantially” may be used herein to emphasize this meaning.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be referenced elsewhere without an ordinal number or with a different ordinal number (e.g., “second” in the specification or another claim).

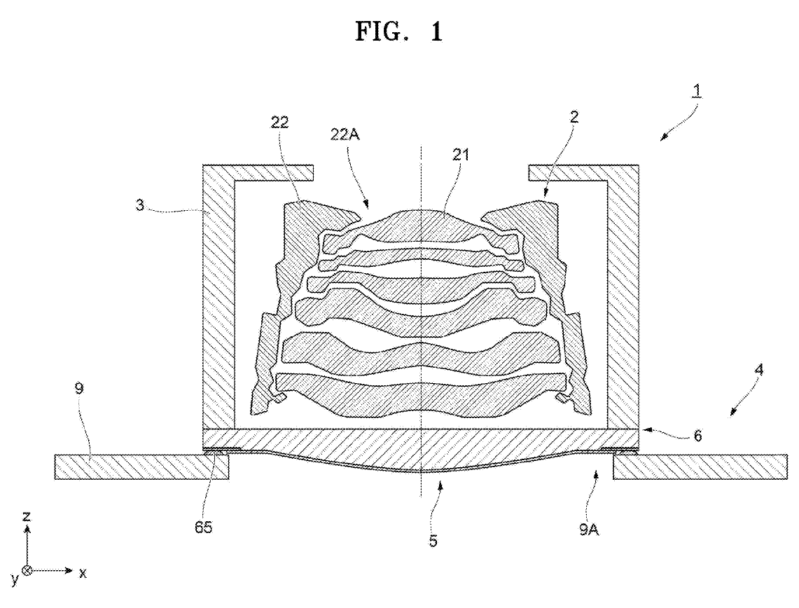

FIG. 1 is a cross-sectional view illustrating a structure of an imaging device 1 according to an embodiment, and is a cross-sectional view taken along an optical axis (indicated by a dash-dot line in FIG. 1) of the imaging device 1. A direction from left to right of the cross-sectional view will be referred to as a x-direction, a direction perpendicular to the cross-sectional view and looking into the cross-section from the front toward the cross-section will be referred to as a y-direction, and a direction from the bottom of the cross-sectional view toward the top of the cross-sectional view will be referred to as a z-direction. The z-direction corresponds to the optical axis direction of the imaging device 1.

Referring to FIG. 1, the imaging device 1 of the present embodiment may include a lens unit 2 that focuses light from a subject, a lens holder 3 that holds the lens unit 2, and an imaging module 4 that receives light transmitted through the lens unit 2 to obtain an image of the subject.

The lens unit 2 may include a plurality of lenses 21 arranged in the z-direction and a barrel 22 that accommodates the plurality of lenses 21 therein.

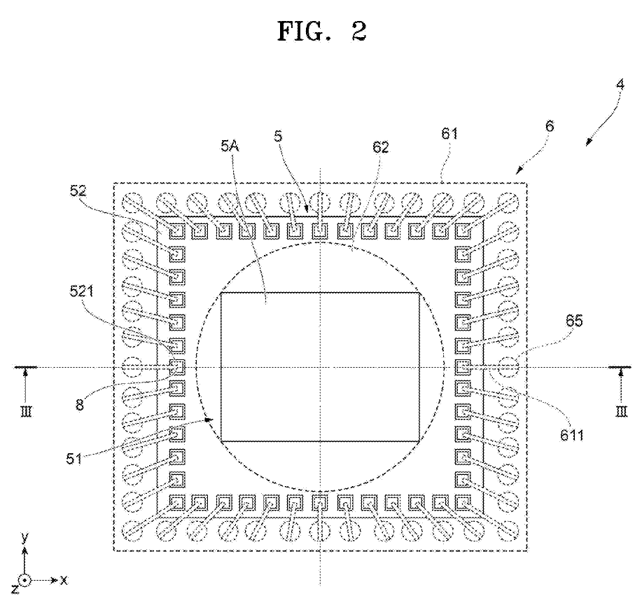

An opening 22A through which light enters the lens unit 2 may be formed in the barrel 22. The plurality of lenses 21 may be retained inside the barrel 22 such that light incident on the opening 22A is focused, by the plurality of lenses 21, on a light-receiving surface 5A (see FIG. 2) of an imaging element 5 of the imaging module 4, which will be described later.

The lens unit 2 may be mounted inside the lens holder 3. The lens holder 3 may retain the lens unit 2 such that the lenses 21 included in the lens unit 2 and the imaging element 5 of the imaging module 4 maintain a fixed positional relationship. The lens holder 3 may hold the lens unit 2 such that an optical axis of the lens unit 2 corresponds to an optical axis of the imaging element 5, and also such that the lens unit 2 and the imaging element 5 have a fixed distance therebetween.

The lens holder 3 may be a retainer. In some embodiments, the lens holder 3 may be mounted on a cover 6 of the imaging module 4, which is described in further detail below. The lens holder 3 may be mounted on a light-receiving surface side of the cover 6. Additionally, as described later, the cover 6 may be integrated with the imaging element 5. Accordingly, misalignment between the optical axis of the lens unit 2 and the optical axis of the imaging element 5 may be prevented, and tilt precision of the lens unit 2 and the imaging element 5 may be improved.

In addition, in some embodiments, when the z-direction is the optical axis direction, a surface (the surface on the top side in FIG. 1) on which light passing through the lens unit 2 is incident on the imaging element 5 or the cover 6 may be referred to as a light-receiving surface. Additionally, a surface opposite to the light-receiving surface in the z-direction (the bottom side in FIG. 1) may be referred to as a lower surface and/or a light-transmitting surface.

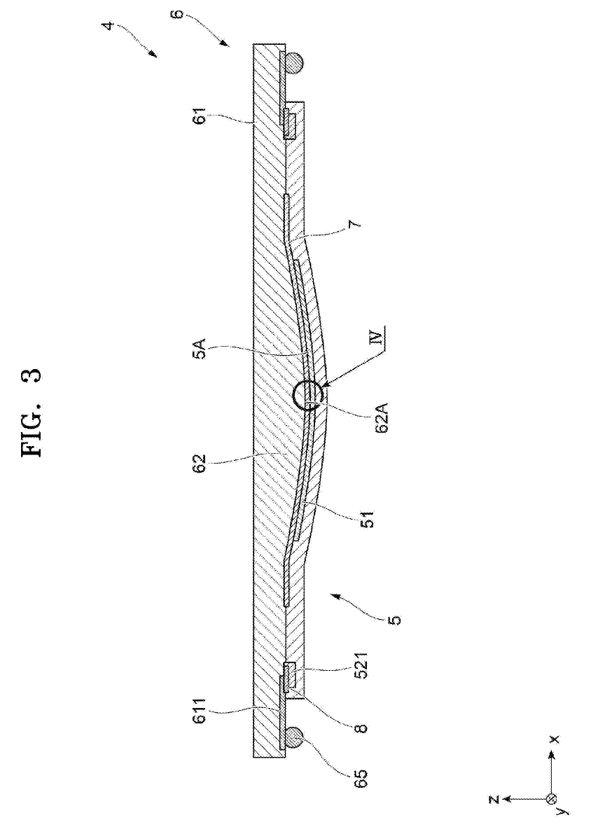

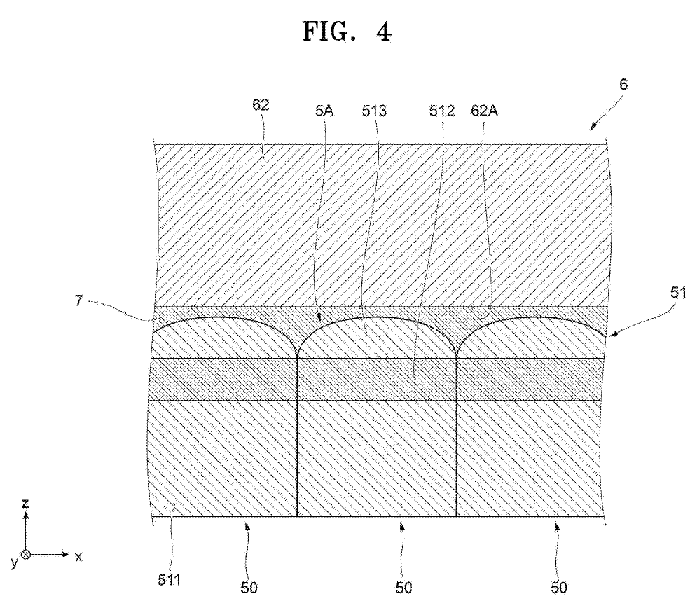

FIG. 2 is a plan view illustrating a structure of the imaging module 4 according to an embodiment, and may correspond to the imaging module 4 of FIG. 1 as viewed along the z-direction from the lens unit 2. In FIG. 2, the cover 6 in front of the imaging element 5 (e.g., above the imaging element 5 in FIG. 1) is indicated by a dotted line, and the structure of the imaging element 5 is indicated by a solid line. FIG. 3 is a cross-sectional view of the imaging module 4 of FIG. 2 taken along section line III-III of FIG. 2, and FIG. 4 is an enlarged view of region IV of FIG. 3.

In FIGS. 2 to 4, an interposer substrate (e.g., interposer substrate 9 of FIG. 1) of the imaging module 4 is omitted for clarity, but may be present in the following embodiments. Description of the imaging module 4 is provided with reference to FIG. 1, and details already described with reference to FIG. 1 may be briefly described or omitted in the following description with the understanding that the previously described details can be applied to the imaging module 4 of FIGS. 2 to 4.

Referring to FIGS. 2 to 4, the imaging module 4 of the present embodiment may include the imaging element 5 that converts light received at the light-receiving surface 5A, which will be described later, into an electrical signal. Additionally, the imaging module 4 may include the cover 6 that covers the light-receiving surface 5A of the imaging element 5. The imaging module 4 may include an adhesive layer 7 provided between the light-receiving surface 5A and the cover 6. Additionally, the imaging module 4 may include a plurality of conductive portions 8 that electrically connect the imaging element 5 to the cover 6. The imaging module 4 may include the cover 6 and the interposer substrate 9 which is electrically connected to the imaging element 5 through the conducting portion 8.

A control device (not shown) may be connected to the imaging module 4 via the interposer substrate 9, and operation of the imaging element 5 may be controlled based on control by the control device.

The imaging element 5 may have the shape of a rectangular plate when viewed along the z-direction. The imaging element 5 may include a pixel array portion 51 in which a plurality of pixels 50 are arranged two-dimensionally. In addition, the imaging element 5 may include a wiring portion 52 that transmits an electric signal between the pixel array portion 51 and a wire of the cover 6 as described below.

The pixel array portion 51 may be arranged on the light-receiving surface of the imaging element 5. Additionally, the pixel array portion 51 may be positioned at a center of the imaging element 5 when viewed in the z-direction. In addition, the pixel array portion 51 may be arranged such that a center thereof corresponds to the optical axis of the lens unit 2.

The pixel array portion 51 may have a rectangular shape with the x-direction as the long axis and the y-direction as the short axis when viewed along the z-direction. Additionally, in the pixel array portion 51, the plurality of pixels 50 may be arranged in a grid shape in the x-direction and the y-direction.

Each pixel 50 of the pixel array portion 51 may include a photoelectric conversion element 511, a color filter 512, and a micro lens 513. The photoelectric conversion element 511 may include a photodiode.

The photoelectric conversion element 511 may be configured as an image sensor such as a charge coupled device (CCD) or complementary metal oxide semiconductor (CMOS). The photoelectric conversion element 511 may convert light received through the micro lens 513 and the color filter 512 into an electrical signal and output the same.

The color filter 512 is provided on the photoelectric conversion element 511. The color filter 512 may have a function of transmitting light of a specific wavelength range (e.g., may block light of wavelengths outside of the specific wavelength range). The color filter 512 may include an R color filter that transmits light in the red (R) wavelength range, a G color filter that transmits light in the green (G) wavelength range, and a B color filter that transmits light in the blue (B) wavelength range.

The micro lens 513 may be provided on the color filter 512. For example, the micro lens 513 may be provided on a light-receiving surface of the color filter 512 in the pixel array portion 51. In the imaging element 5 of the present embodiment, a light-receiving surface of the micro lens 513 among the pixel array portion 51 may be the light-receiving surface 5A of the imaging element 5. In the present embodiment, the light-receiving surface 5A may have a rectangular shape with the x-direction as the long axis and the y-direction as the short axis when viewed in a plane from the z-direction.

The micro lens 513 may be a plano-convex spherical lens that focuses incident light onto the photoelectric conversion element 511 through the color filter 512. The micro lens 513 may include a material having a higher refractive index than the cover 6 and the adhesive layer 7.

The wiring portion 52 may be continuously provided around the pixel array portion 51 and in an area on the same surface as the light-receiving surface 5A of the pixel array portion 51. The wiring portion 52 may have a rectangular shape when viewed along the z-direction.

The wiring portion 52 may include wires with each of the wires electrically connected to a corresponding photoelectric conversion element 511 of the pixel array portion 51 and configured to transmit an electric signal from the corresponding photoelectric conversion element 511. The wiring portion 52 may have a structure in which wires are formed on a surface or inside of a substrate. The substrate may include, for example, silicon (Si).

Additionally, the wiring portion 52 may include a plurality of electrode pads 521 to which the conducting portions 8 are connected. The plurality of electrode pads 521 may be provided at the light-receiving surface side of the imaging element 5 among the wiring portion 52, which is a surface facing the cover 6. Additionally, the wires of the wiring portion 52 may be electrically connected to corresponding wires of the cover 6 through the electrode pad 521 and the conducting portion 8.

In the present embodiment, the plurality of electrode pads 521 may be arranged along the outer periphery of the wiring portion 52, which is rectangular in shape. Additionally, the plurality of electrode pads 521 may be arranged around the light-receiving surface 5A.

The imaging element 5 of the present embodiment may be curved such that the light-receiving surface 5A is concave toward the side opposite to the cover 6, e.g., toward the side opposite to the light-receiving surface as shown in FIG. 3. In addition, the imaging element 5 may have the light-receiving surface 5A curved along a light-transmitting surface 62A of the cover 6, which faces the light-receiving surface 5A and is described later.

Additionally, the imaging element 5 may be arranged within a space 9A formed at a center of the interposer substrate 9 in which at least the light-receiving surface 5A is formed.

The shape of the light-receiving surface 5A of the imaging element 5, the relationship between the imaging element 5 and the cover 6, and the effect of the curve of the imaging element 5 will each be described in detail later.

The cover 6 may be provided at the light-receiving surface of the imaging element 5 in the imaging module 4 and cover the light-receiving surface 5A. The cover 6 may include a material that is capable of transmitting visible light. The cover 6 may include, for example, glass. However, the material constituting the cover 6 is not limited to glass.

The cover 6 may include a base portion 61 that is flat. In addition, the cover 6 may include a protrusion 62 which is formed as a portion integral with the base portion 61 and protrudes from the base portion 61 toward the lower surface of the cover 6 (the side facing the light-receiving surface of the cover 6).

The base portion 61 may have a rectangular shape when viewed in the z-direction. The base portion 61 may have a larger area when viewed in the z-direction than the wiring portion 52 of the imaging element 5. Accordingly, an outer periphery portion of the base portion 61 may be exposed to the outside more than the wiring portion 52 (e.g., may extend beyond the wiring portion 52 in the x-direction and the y-direction).

In the base portion 61, a wire 611 may be formed that is connected to the electrode pad 521 through the conducting portion 8 and transmits an electric signal. The wire 611 may be one of a plurality of wires having the same structure. The wire 611 may be formed on a lower surface of the base portion 61. The wire 611 may be formed on the outer periphery portion of the base portion 61, which is exposed outside the wiring portion 52 of the imaging element 5 (e.g., is not covered by the wiring portion 52). In addition, the wire 611 may be provided at the light-transmitting surface 62A of the protrusion 62, which is to be described later. The plurality of wires may surround the protrusion 62 when viewed along the z-direction.

The wire 611 may be formed, for example, by metalizing the base portion 61 of the cover 6.

The wire 611 may allow a terminal located inward of the periphery of the base portion 61, to be connected to the electrode pad 521 of the imaging element 5 through the conducting portion 8.

In addition, the wire 611 may allow a terminal located on the periphery of the base portion 61, to be connected to the interposer substrate 9 through an electrode 65. The electrode 65 may be formed by a bump including, for example, gold.

The protrusion 62 may be provided at the center of the base portion 61 when viewed along the z-direction. The protrusion 62 may have a curved shape such that the light-transmitting surface 62A that is facing the light-receiving surface 5A of the imaging element 5 protrudes toward the imaging element 5.

In the present embodiment, the shape of the protrusion 62 viewed along the z-direction may be circular with respect to the optical axis of the imaging device 1 (e.g., see FIG. 1). The light-transmitting surface 62A may have a spherical shape protruding toward the imaging element 5 with respect to the optical axis (e.g., the light-transmitting surface may have the curvature of a portion of a sphere). Additionally, the light-transmitting surface 62A may be a surface in which a curvature in the x-direction and a curvature in the y-direction are substantially the same.

The adhesive layer 7 may be provided between the light-receiving surface 5A of the imaging element 5 and the light-transmitting surface 62A of the cover 6. The adhesive layer 7 may secure the imaging element 5 and the cover 6 with each other by bonding the light-receiving surface 5A and the light-transmitting surface 62A to each other. The adhesive layer 7 may include a material that is transparent to visible light.

In the imaging device 1 of the present embodiment, if the imaging element 5 and the cover 6 were to be directly stacked without using the adhesive layer 7, a gap may be formed between the light-receiving surface 5A and the light-transmitting surface 62A. As described above, as the imaging element 5 has the micro lens 513 on the light-receiving surface 5A, a gap is likely to be formed between the light-receiving surface 5A and the light-transmitting surface 62A due to the unevenness of the micro lens 513. However, as the imaging device 1 of the present embodiment has the adhesive layer 7, a gap between the light-receiving surface 5A of the imaging element 5 and the light-transmitting surface 62A of the cover 6 may be filled by the adhesive layer 7.

In addition, as the imaging device 1 of the present embodiment includes the adhesive layer 7, when the light-receiving surface 5A and the light-transmitting surface 62A contact each other, the adhesive layer 7 acts as a buffer, thereby suppressing a load from being applied to the micro lens 513.

The adhesive layer 7 may be formed by a material having a similar refractive index to that of the cover 6. A refractive index of the adhesive layer 7 and the refractive index of the cover 6 may differ by 0.2 or less, and in some embodiments, may be substantially the same. By making the difference in refractive index between the adhesive layer 7 and the cover 6 0.2 or less, it is easy to suppress the reflectance at an interface between the adhesive layer 7 and the cover 6 due to the difference in refractive index, to less than 1%.

Additionally, the adhesive layer 7 may include a material having a lower refractive index than the micro lens 513 of the imaging element 5. As the refractive indices of the adhesive layer 7, the cover 6, and the micro lens 513 satisfy the above-described relationship, light incident on the cover 6 may easily pass through the adhesive layer 7 and the micro lens 513 and be focused on the photoelectric conversion element 511 of the imaging element 5. The adhesive layer 7 may include, for example, acrylic. However, the material constituting the adhesive layer 7 is not limited to acrylic.

The conducting portion 8 may electrically connect the electrode pad 521 provided in the wiring portion 52 of the imaging element 5 to the wire 611 provided in the base portion 61 of the cover 6. The conducting portion 8 may include a film having anisotropic conductivity (hereinafter referred to as an "anisotropic conductive film"), or a bump including a metal or alloy.

The anisotropic conductive film may be a film that has conductive characteristics in the z-direction, which is a thickness direction, and insulating characteristics in the x-direction and the y-direction, which are plane directions. Additionally, the bump may include, for example, gold, silver, copper, nickel, solder, etc. In the imaging element 5 of the present embodiment, the bump may include, for example, gold.

The interposer substrate 9 may include a redistribution layer connected to the imaging element 5 through the electrode 65, the wire 611, and the conducting portion 8 provided on the cover 6.

In the interposer substrate 9, the space 9A may penetrate through the interposer substrate 9 in the thickness direction (z-direction) and may be formed in the center thereof.

In the imaging module 4 of the present embodiment, the light-receiving surface 5A of the imaging element 5 may be arranged in the space 9A formed in the interposer substrate 9. Accordingly, the imaging module 4 may be made thinner compared to, for example, a case where the interposer substrate 9 does not have the space 9A formed therein and the light-receiving surface 5A of the imaging element 5 is positioned at a misaligned position in the thickness direction (z-direction) with respect to the interposer substrate 9.

In the imaging module 4 of the present embodiment, as described above, the light-receiving surface 5A of the imaging element 5 may have a curved shape along the light-transmitting surface 62A of the cover 6 (e.g., may have a shape that is complementary to the shape of the light-transmitting surface 62A). In the present embodiment, the light-receiving surface 5A of the imaging element 5 may be formed as a spherical shape that is concave toward the cover 6, and may conform to the light-transmitting surface 62A. In addition, the light-receiving surface 5A may be a curved surface in which the curvature in the x-direction and the curvature in the y-direction are substantially the same as each other.

For reference, in imaging modules in which a light-receiving surface of an imaging element is flat, the focus of light incident on a lens at the outer periphery portion of the light-receiving surface may be misaligned with respect to the light-receiving surface, causing blurring in an image obtained by the imaging element. If the light-receiving surface is supported and curved from the back side to suppress image blurring, foreign substances such as dust may adhere to the light-receiving surface if the light-receiving surface is exposed from beneath a cover.

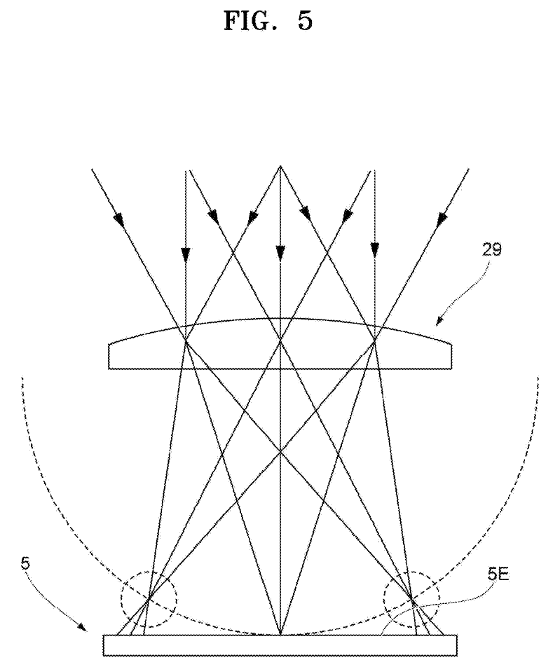

FIG. 5 is a conceptual diagram showing an example of a relationship between light incident on a lens 29 and a flat light-receiving surface 5E in an imaging element 5.

Referring to FIG. 5, in general, the position of the focus of light incident on the lens 29 is closer to the lens 29 at locations farther away from an optical axis of the lens 29. For this reason, as illustrated in FIG. 5, if the lens 29 and the imaging element 5 are arranged such that the position of the focus of the light incident on the lens 29 and the center of the light-receiving surface 5E are aligned with each other, the position of the focus at the outer periphery portion of the light-receiving surface 5E may be misaligned with respect to the light-receiving surface 5E. In this case, blurring may occur in the outer periphery portion of an image obtained by the imaging element 5.

A method of suppressing blurring in the outer periphery portion of an image obtained by the imaging element may include a method of correcting the position of the focus by increasing the number of lenses included in a lens unit. However, when the number of lenses of the lens unit is increased, the imaging device may be increased in size. In particular, when using the imaging device as a camera for a smartphone, there is a strong demand for miniaturization and light weight of the imaging device, and thus, enlargement of the imaging device is not desirable.

In the imaging element 5 of the present embodiment, the light-receiving surface 5A of the imaging element 5 may be curved to be concave toward the side facing the cover 6, and may conform to the curve of the light-transmitting surface 62A of the cover 6. Accordingly, the distance between the light-receiving surface 5A of the imaging element 5 in the outer periphery portion, which is further away from the optical axis of the lens unit 2, may be closer to the lens unit 2.

Accordingly, misalignment of the position of the focus of light incident on the lens unit 2 at the outer periphery portion of the light-receiving surface 5A, may be prevented. Accordingly, image blurring in the outer periphery portion of an image obtained by the imaging element 5 may be prevented.

For example, in the imaging element 5 of the present embodiment, the light-receiving surface 5A of the imaging element 5 may be curved and conform to the curve of the light-transmitting surface 62A of the cover 6. For example, the light-receiving surface 5A and the light-transmitting surface 62A may be curved surfaces with the same curvature. Accordingly, a distance between the light-receiving surface 5A and the light-transmitting surface 62A and a thickness of the adhesive layer 7 may be constant over the entire light-receiving surface 5A.

According to this configuration, for example, compared to a case where the light-receiving surface 5A is not conformal with the light-transmitting surface 62A, light incident on the cover 6 over the entire area of the light-receiving surface 5A may be easily focused on the photoelectric conversion element 511 of the imaging element 5.

Additionally, in the imaging module 4 of the present embodiment, the light-receiving surface 5A of the imaging element 5 may be covered by the cover 6 with the adhesive layer 7 therebetween. Additionally, in the imaging module 4, there may be no gap between the light-receiving surface 5A of the imaging element 5 and the cover 6. Accordingly, for example, compared to a case where the light-receiving surface 5A of the imaging element 5 is exposed, attachment of foreign substances such as dust to the light-receiving surface 5A may be prevented.

Additionally, in the imaging element 5, the outer periphery portion of the wiring portion 52 located around the light-receiving surface 5A and having the electrode pad 521 formed thereon may face the base portion 61 of the cover 6. Additionally, the outer periphery portion of the wiring portion 52 may be flat in line with the base portion 61 that is flat. Accordingly, in the imaging module 4 of the present embodiment, compared to a case where the outer periphery portion of the wiring portion 52 is curved, the conducting portion 8 may be easily connected to the electrode pad 521, and accordingly, poor contact between the electrode pad 521 and the conducting portion 8 may be suppressed.

In the imaging module 4 of the present embodiment, the imaging element 5 may include the electrode pad 521 as an example of a first conductive portion electrically connected to the cover 6. Additionally, in the imaging module 4 of the present embodiment, the cover 6 may include the wire 611 as an example of a second conductive portion electrically connected to the imaging element 5. The shapes of the first conducting portion of the imaging element 5 and the second conducting portion of the cover 6 described above are examples, and the shapes are not particularly limited as long as the imaging element 5 is electrically connected to the cover 6. For example, the imaging element 5 may have a wire as an example of the first conductive portion, and the cover 6 may have electrode pads as an example of the second conductive portion.

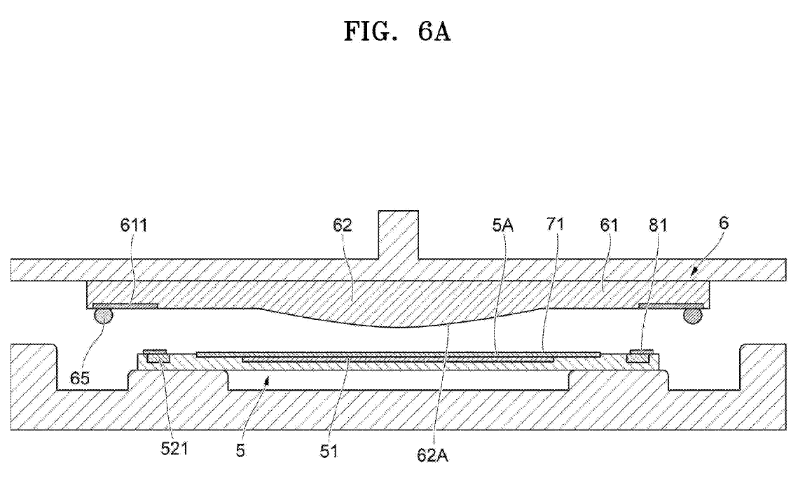

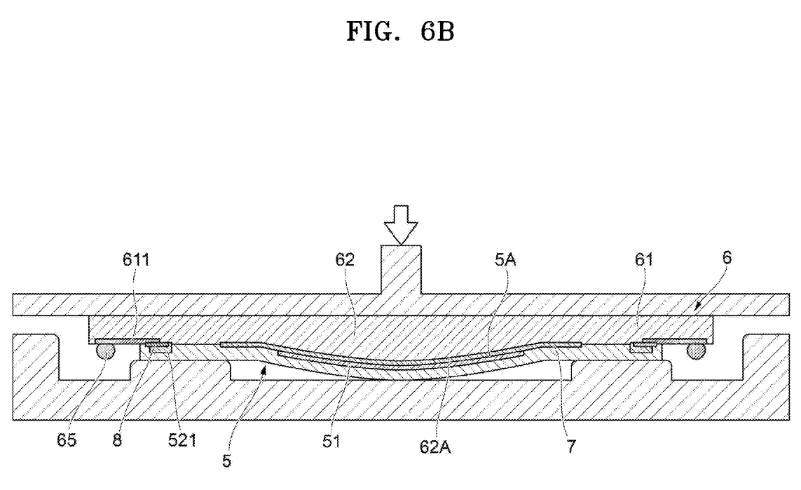

FIGS. 6A and 6B are cross-sectional views showing a method of manufacturing the imaging module 4, according to an embodiment.

Referring to FIGS. 6A and 6B, in the method of manufacturing the imaging module 4, of the present embodiment, the imaging element 5 that is flat initially may be used. First, as illustrated in FIG. 6A, an anisotropic conductive film 81 or metal material, which material forms the conducting portion 8, is loaded on the electrode pad 521 of the imaging element 5. Here, for example, an anisotropic conductive film 81 may be loaded on the electrode pad 521.

Additionally, an adhesive 71, which material forms the adhesive layer 7, is applied on the light-receiving surface 5A of the imaging element 5. The imaging element 5 on which the anisotropic conductive film 81 is loaded and the adhesive 71 is applied is installed on a stage provided in a manufacturing device of the imaging module 4.

Next, the cover 6 having the electrode 65 provided on the wire 611 is stacked onto the imaging element 5 on a stage using a collet provided in the manufacturing device of the imaging module 4. Here, the imaging element 5 and the cover 6 are stacked such that the terminal of the wire 611 and the anisotropic conductive film 81 overlap each other in the vertical direction. Additionally, the imaging element 5 and the cover 6 are stacked such that the light-receiving surface 5A faces the protrusion 62 of the cover 6 with the adhesive 71 therebetween.

Then, the cover 6 is pressed toward the imaging element 5 using the collet, and the inside of the manufacturing device is evacuated. Through this evacuation, the space between the cover 6 and the imaging element 5 is evacuated, and accordingly, the imaging element 5 may be deformed according to the cover 6. The light-receiving surface 5A of the imaging element 5 may be deformed into a curved shape conforming to the shape of the light-transmitting surface 62A of the cover 6 which faces the light-receiving surface 5A.

Afterwards, the inside of the manufacturing device is heated to harden the anisotropic conductive film 81 and also to harden (e.g., cure) the adhesive 71. Accordingly, the conducting portion 8 may be formed as illustrated in FIG. 6B, and the electrode pad 521 of the imaging element 5 and the wire 611 of the cover 6 are connected to each other by the conducting portion 8. Also, the adhesive layer 7 is formed from the adhesive 71, and the imaging element 5 and the cover 6 are secured together by the adhesive layer 7.

According to the above, the imaging module 4 illustrated as in FIG. 3 may be obtained.

Afterwards, by mounting the interposer substrate 9 on the cover 6 through the electrode 65 and mounting the lens unit 2, the imaging device 1 illustrated in FIG. 1 may be manufactured.

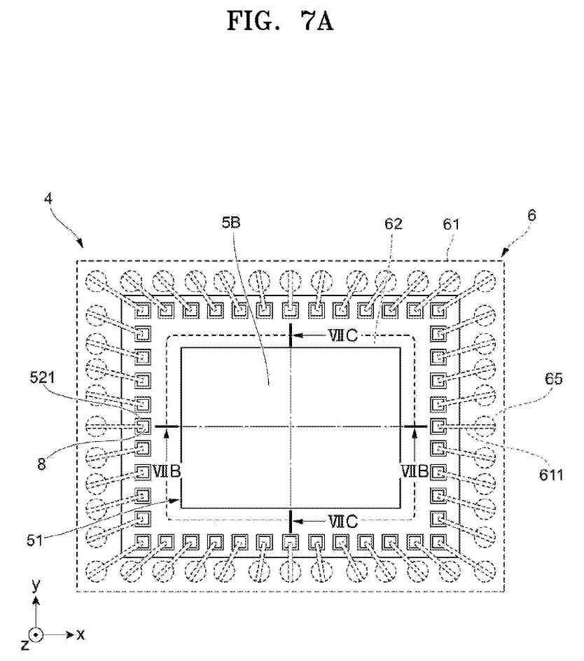

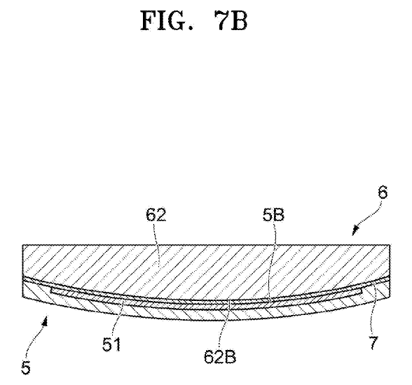

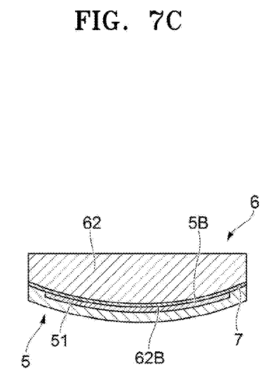

FIGS. 7A to 7C are a plan view and cross-sectional views showing the structure of an imaging module according to an embodiment, wherein FIG. 7A is a plan view of the imaging module 4 as seen from the lens unit (2, see FIG. 1) side along the z-direction, FIG. 7B is a cross-sectional view of the imaging module 4 taken along line VIIB-VIIB of FIG. 7A, and FIG. 7C is a cross-sectional view of the imaging module 4 taken along line VIIC-VIIC of FIG. 7A. In FIGS. 7A to 7C, the interposer substrate 9 is omitted for clarity. Description is given together with reference to FIG. 1, and the details already described with reference to FIGS. 1 to 6B may be briefly described or omitted with the understanding that the previous descriptions are applicable.

Referring to FIGS. 7A to 7C, the imaging module 4 of the present embodiment may differ from the imaging module 4 of FIG. 2 in the shape of the protrusion 62 and the light-transmitting surface 62B of the cover 6 and the shape of a light-receiving surface 5B of the imaging element 5. In the imaging module 4 of the present embodiment, the protrusion 62 of the cover 6 may have a rectangular shape with rounded corners, with the x-direction as the long axis and the y-direction as the short axis, according to the light-receiving surface 5B which is in a rectangular shape. Similarly, the shape of a horizontal cross-section of the protrusion 62 cut in an xy plane may have a rectangular shape with rounded corners, with the x-direction as the long axis and the y-direction as the short axis. In addition, as the horizontal cross-section of the protrusion 62 cut in the xy plane faces toward the light-receiving surface 5B, a horizontal cross-sectional area of the protrusion 62 cut in the xy plane may gradually decrease along the z-direction.

Accordingly, the light-transmitting surface 62B of the protrusion 62 may have a curved shape to protrude toward the imaging element 5. Additionally, the light-transmitting surface 62B may be a curved surface with different curvatures in the x-direction and the y-direction. The light-transmitting surface 62B may be a surface having curvature in the x-direction, which is smaller than that in the y-direction.

In the imaging module 4 of the present embodiment, the x-direction and the y-direction are examples of two orthogonal directions.

Additionally, the light-receiving surface 5B of the imaging element 5 may have a curved shape that is concave toward the side opposite to the cover 6 along the light-transmitting surface 62B. In addition, the light-receiving surface 5B may be a curved surface with a smaller curvature in the x-direction than in the y-direction.

According to this configuration, in the imaging module 4 of the present embodiment, misalignment of the position of the focus of light incident on the lens unit 2 at the outer periphery portion of the light-receiving surface 5B, from the light-receiving surface 5B, may be prevented. Accordingly, image blurring in the outer periphery portion of an image obtained by the imaging element 5 may be prevented.

Here, in the imaging module 4 of the present embodiment, the shape of the protrusion 62 of the cover 6 when viewed in the z-direction has a rectangular shape with rounded corners according to the shape of the light-receiving surface 5B of the imaging element 5, and thus, the width of the cover 6 in the y-direction may be smaller than the imaging module 4 of FIG. 2. Accordingly, the imaging module 4 and the imaging device 1 may be miniaturized compared to the imaging module 4 of FIG. 2, in which the shape of the protrusion 62 of the cover 6 is circular when viewed in the z-direction.

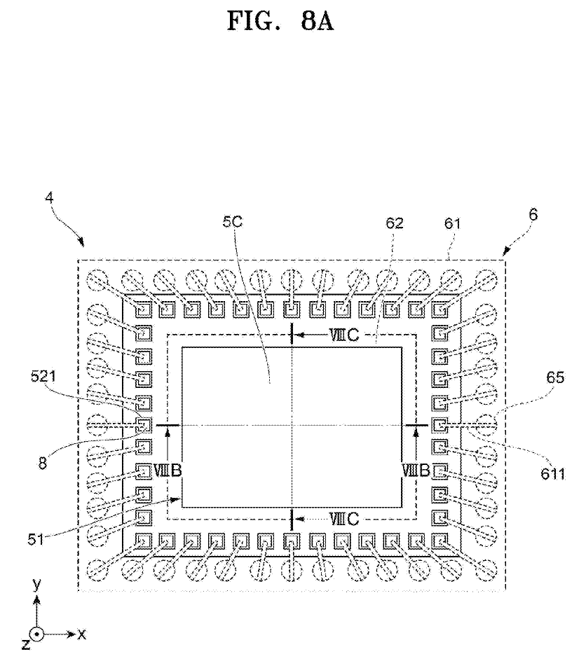

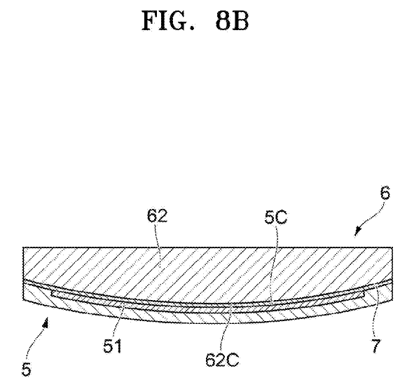

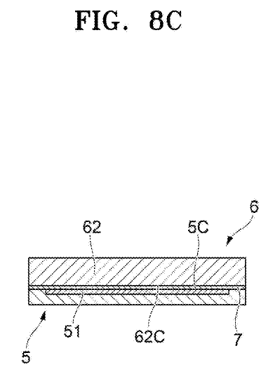

FIGS. 8A to 8C are a plan view and cross-sectional views showing the structure of an imaging module according to an embodiment, wherein FIG. 8A is a plan view of the imaging module 4 as seen from the lens unit (see lens unit 2 of FIG. 1) along the z-direction, FIG. 8B is a cross-sectional view of the imaging module 4 taken along line ⅧB-ⅧB of FIG. 8A, and FIG. 8C is a cross-sectional view of the imaging module 4 taken along line ⅧC-ⅧC of FIG. 8A. In FIGS. 8A to 8C, the interposer substrate 9 is omitted for clarity. Description is given together with reference to FIG. 1, and the details already described with reference to FIGS. 1 to 7C may be briefly described or omitted with the understanding that they may be applied to the present embodiment.

Referring to FIGS. 8A to 8C, the imaging module 4 of the present embodiment may differ from the imaging module 4 of FIGS. 2 and 7A in the shape of the protrusion 62 and the light-transmitting surface 62C of the cover 6 and the shape of the light-receiving surface 5C of the imaging element 5. The imaging module 4 of the present embodiment may have a rectangular shape with the x-direction as the long axis and the y-direction as the short axis, according to the rectangular light-receiving surface 5C in which the shape of the protrusion 62 is viewed along the z-direction in the cover 6.

In the imaging module 4 of the present embodiment, the cover 6 may have a cylindrical surface shape in which the light-transmitting surface 62C has a curvature in the x-direction, but no curvature in the y-direction. Additionally, the light-receiving surface 5C of the imaging element 5 may be curved to be concave relative to the side opposite to the cover 6 along the light-transmitting surface 62C. In addition, the light-receiving surface 5C may have a cylindrical surface shape that has a curvature in the x-direction but no curvature in the y-direction.

According to this configuration, in the imaging module 4 of the present embodiment, misalignment of the position of the focus of light incident on the lens unit 2 at both ends of the light-receiving surface 5C in the x-direction, from the light-receiving surface 5C, may be prevented. Accordingly, blurring, at both ends of the x-direction, in an image obtained by the imaging element 5 may be prevented.

In the imaging element 5, the greater the distance from the optical axis, the more the position of the focus of light incident from the lens unit 2 may tend to shift toward the lens unit 2. However, in the imaging module 4 of the present embodiment, as the light-receiving surface 5C has a curvature in the x-direction, which is the long axis direction of a rectangular shape, misalignment of the position of the focus of light incident from the lens unit 2, from the light-receiving surface 5C at both ends in the x-direction of the light-receiving surface 5C that are far from the optical axis, may be prevented.

In the imaging module 4 of the present embodiment, the cover 6 may have a cylindrical surface shape in which the light-transmitting surface 62C has a curvature in the x-direction but no curvature in the y-direction, and thus, the cover 6 may be easily formed compared to a case in which there is curvature in both the x-direction and the y-direction.

In addition, in the manufacture of the imaging module 4, when the protrusion 62 of the cover 6 is pressed against the light-receiving surface 5C to deform the imaging element 5, the imaging element 5 may be deformed with a smaller pressing force compared to when the light-transmitting surface 62C has curvature in both the x-direction and the y-direction. Accordingly, the imaging module 4 may be easily performed.

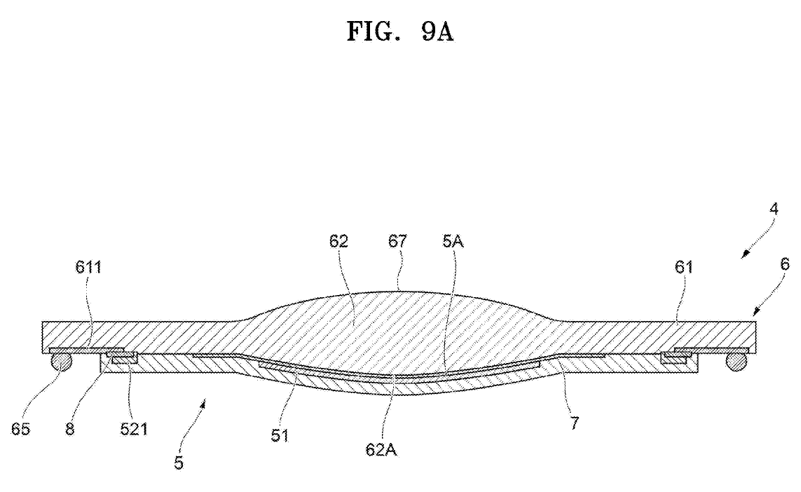

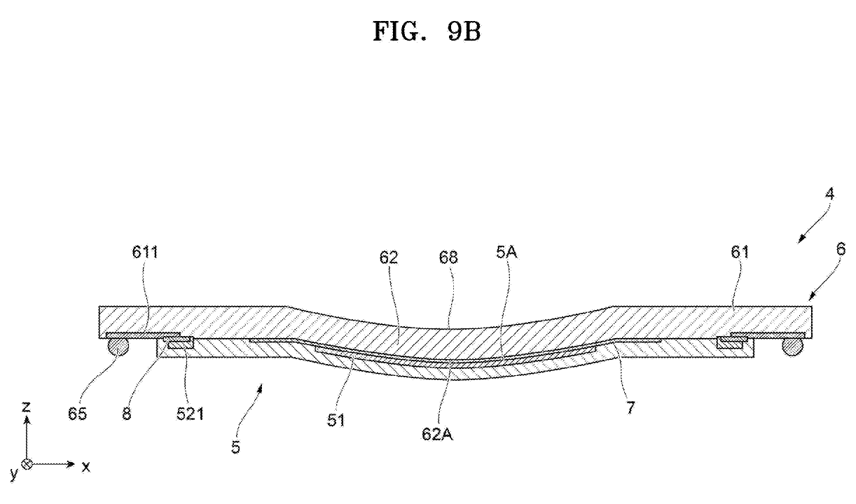

FIGS. 9A and 9B are cross-sectional views showing the structure of an imaging module according to an embodiment, and are cross-sectional views corresponding to FIG. 3. Description is given together with reference to FIG. 1, and the details already described with reference to FIGS. 1 to 8C are briefly described or omitted. In the following description, the imaging module 4 of the embodiment of FIG. 2 is described as an example, but each of the embodiments of FIGS. 9A and 9B may also be applied to the imaging module 4 of FIGS. 7A and 8A.

Referring to FIGS. 9A and 9B, as illustrated in FIGS. 9A and 9B, in the imaging module 4 of the present embodiment, a light-receiving surface of the cover 6 to the light-transmitting surface 62A of the cover 6 may be curved. For example, in the imaging module 4, a light-receiving surface of the cover 6 located on the light incident side among the cover 6 and facing the lens (21, see FIG. 1) of the lens unit (2, see FIG. 1) may be curved.

In the cover 6 of the embodiment of FIG. 9A, the light-receiving surface 67 of the cover, which is a surface opposite to the light-transmitting surface 62A of the cover, may be curved to protrude toward the light incident side (light-receiving side). In addition, in the cover 6 of the embodiment of FIG. 9B, the light-receiving surface 68 of the cover 6 opposite to the light-transmitting surface 62A of the cover may be a curved surface that is concave downward.

In the imaging module 4 of the present embodiment, as the opposite surfaces of the cover 6 (e.g., light-receiving surface 67 and light-transmitting surface 62A) are curved, the opposite surfaces may function as a lens that focuses light passing through the lens unit 2 and entering the cover 6, onto the photoelectric conversion element 511. Accordingly, the number of lenses 21 of the lens unit 2 may be reduced, and an imaging device (see imaging device 1 of FIG. 1) that is smaller and lighter may be obtained. In addition, the shape of the opposite surfaces 67 and 68 of the cover 6 may be determined according to the optical characteristics of the lenses 21 of the lens unit 2.

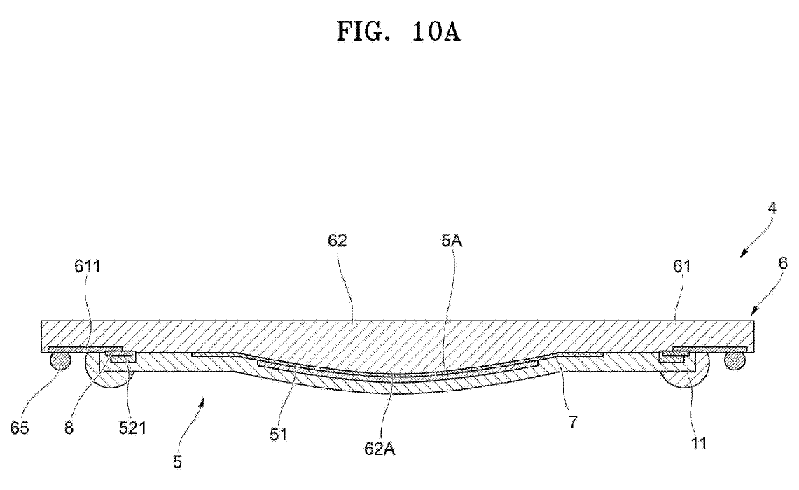

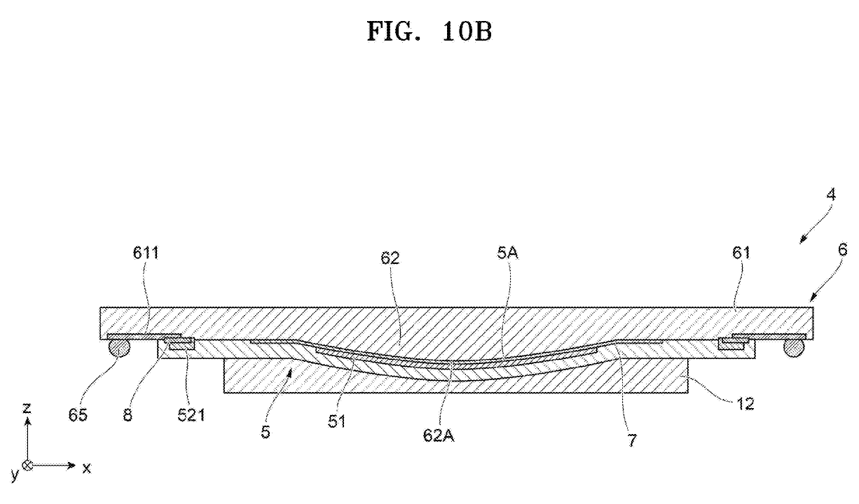

FIGS. 10A and 10B are cross-sectional views showing the structure of an imaging module according to an embodiment, and are cross-sectional views corresponding to FIG. 3. Description is given together with reference to FIG. 1, and the details already described with reference to FIGS. 1 to 9B may be briefly described or omitted with the understanding that the previous descriptions may be applied to the present embodiment.

Referring to FIGS. 10A and 10B, as illustrated in FIG. 10A, the imaging module 4 of the present embodiment may include a resin layer 11 that protects the electrode pads 521 arranged along the outer periphery of the imaging element 5. The resin layer 11 may be an example of a protective spacer.

As the imaging module 4 of the present embodiment includes the resin layer 11, loads on the electrode pad 521 and the electrode 65 and the wire 611 of the cover 6 connected to the electrode pad 521 may be suppressed. Accordingly, a short circuit between the imaging element 5 and the cover 6 may be prevented. The resin layer 11 may include, for example, epoxy. However, the material of the resin layer 11 is not limited to epoxy.

In addition, as illustrated in FIG. 10B, the imaging module 4 of the present embodiment may further include a heat dissipation member 12 that dissipates heat from the imaging element 5. The heat dissipation member 12 may be arranged to contact a surface of the imaging element 5 that is opposite to the light-receiving surface 5A of the imaging element 5. When viewed along the z-direction, the area of the heat dissipation member 12 may be larger than the pixel array portion 51 of the imaging element 5 and the heat dissipation efficiency may be increased by the heat dissipation member 12.

As the imaging module 4 of the present embodiment includes the heat dissipation member 12, heat generated from the photoelectric conversion element 511 of the imaging element 5 may be easily dissipated. Accordingly, the deterioration of the image quality of the image obtained by the imaging element 5 due to the increase in the temperature of the photoelectric conversion element 511 may be prevented. The heat dissipation member 12 may include, for example, a metal with high thermal conductivity such as aluminum or copper, a graphite sheet, a Peltier element, etc. However, the material of the heat dissipation member 12 is not limited to the materials described above.

A method of manufacturing an imaging device, according to an embodiment, includes: preparing an imaging element having a light-receiving surface for receiving light; preparing a cover covering the imaging element; and coupling the imaging element to the cover, wherein the cover is curved such that a light-transmitting surface thereof facing the light-receiving surface of the imaging element protrudes toward the imaging element, the imaging element is stacked on the light-transmitting surface of the cover, and the light-receiving surface may be concavely curved toward a side of the imaging element that is opposite to the light-receiving surface facing the cover.

In an embodiment, the imaging device may include an electrode pad near the periphery of the light-receiving surface, and the preparing of the imaging element may include loading a material forming a conducting portion on the electrode pad of the imaging element, applying an adhesive on the light-receiving surface of the imaging device, and installing the imaging element on a stage.

In an embodiment, the material forming the conducting portion may include at least one of an anisotropic conductive film and a bump.

In an embodiment, the coupling of the imaging element to the cover may include stacking the cover on the imaging element, pressing the cover toward the imaging element, and curing the material forming the conducting portion and the adhesive.

In an embodiment, the cover may include a wire positioned at a periphery of the light-transmitting surface of the cover, and in the stacking of the cover on the imaging element, a terminal of the wire may be stacked to overlap the material forming the conducting portion.

In an embodiment, in the stacking of the cover on the imaging element, the light-receiving surface may be stacked to face a protruding portion of the cover, with the adhesive therebetween.

In an embodiment, in the pressing of the cover toward the imaging element, evacuation of fluid between the cover and the imaging element may be performed.

In an embodiment, in the curing of the material of the conducting portion and the adhesive, an inside of a manufacturing device in which the imaging element and the cover are arranged may be heated.

In an embodiment, after the coupling of the imaging element to the cover, the method may further include mounting the cover on an interposer substrate and mounting a lens unit on the cover.

In an embodiment, the interposer substrate may have a space formed in the center thereof in which at least the light-receiving surface of the imaging element is arranged and the interposer substrate may have a redistribution layer, and in the mounting of the cover on the interposer substrate, the redistribution layer may be connected to the wire of the cover through an electrode of the cover.

While the embodiments have been described, the disclosure is not limited to the above-described embodiments. For example, various modifications or combinations may be made without conflicting with the technical spirit of the disclosure. In addition, although the disclosure has been described with reference to the embodiments illustrated in the drawings, these are merely examples, and those skilled in the art will understand that various modifications and equivalent other embodiments may be made therefrom. Therefore, the scope of the disclosure is defined by the appended claims.

While the disclosure has been particularly shown and described with reference to embodiments thereof, it will be understood that various changes in form and details may be made therein without departing from the spirit and scope of the following claims.

What is claimed is:

1. An imaging module comprising:
an imaging element having a light-receiving surface configured to receive light; and
a cover covering the light-receiving surface of the imaging element,
wherein the cover is curved such that a light-transmitting surface of the cover that faces the light-receiving surface protrudes toward the imaging element, and
wherein the imaging element is stacked on the light-transmitting surface of the cover, and the light-receiving surface is concavely curved toward an opposite side of the imaging element that is opposite to the light-transmitting surface.

2. The imaging module of claim 1, wherein the light-receiving surface is curved to along the light-transmitting surface of the cover.

3. The imaging module of claim 1, wherein
the imaging element includes an electrode pad located at a periphery of the light-receiving surface, and
the cover includes a wire connected to the electrode pad and the wire located at a periphery of the light-transmitting surface.

4. The imaging module of claim 3, wherein the electrode pad of the imaging element and the wire of the cover are connected to each other by at least one of an anisotropic conductive film and a bump.

5. The imaging module of claim 3, further comprising a protective spacer arranged on an outer periphery of the imaging element and protecting the electrode pad.

6. The imaging module of claim 1, further comprising an interposer substrate which has a space formed therein in which at least the light-receiving surface of the imaging element is arranged, and which is connected to a wire of the cover.

7. The imaging module of claim 1, further comprising an adhesive layer between the cover and the imaging element,
wherein a difference between a refractive index of the cover and a refractive index of the adhesive layer is 0.2 or less.

8. The imaging module of claim 7, wherein
the imaging element includes a micro lens on the light-receiving surface, and
a refractive index of the adhesive layer is lower than a refractive index of the micro lens.

9. The imaging module of claim 1, further comprising a heat dissipation member disposed on an opposite surface of the imaging element that is opposite to the light-receiving surface of the imaging element and that is configured to dissipate heat from the imaging element.

10. The imaging module of claim 1, wherein a light-receiving surface of the cover that is opposite to the light-transmitting surface is curved.

11. The imaging module of claim 1, wherein
the light-receiving surface of the imaging element has a first curvature in a first direction and a second curvature in a second direction orthogonal to the first direction, wherein the first curvature is different from the second curvature.

12. The imaging module of claim 1, wherein
the light-receiving surface of the imaging element has a first curvature in a first direction and no curvature in a second direction orthogonal to the first direction.

13. An imaging device comprising:
an imaging module comprising an imaging element having a light-receiving surface, and a cover covering the light-receiving surface of the imaging element;
a lens configured to focus light on the light-receiving surface of the imaging element; and
a retainer retaining the lens,
wherein the cover is curved such that a light-transmitting surface of the cover that faces the light-receiving surface of the imaging element protrudes toward the imaging element, and
wherein the imaging element is stacked on the light-transmitting surface of the cover, and the light-receiving surface is concavely curved toward an opposite side of the imaging element that is opposite to the light-receiving surface.

14. The imaging device of claim 13, wherein the retainer is mounted on the cover.

15. The imaging device of claim 13, wherein
the imaging element includes an electrode pad at a periphery of the light-receiving surface, and
the cover includes a wire connected to the electrode pad and the wire is located at the periphery of the light-transmitting surface.

16. The imaging device of claim 13, wherein the imaging module further comprises an interposer substrate that has a space formed therein in which at least the light-receiving surface of the imaging element is arranged, and which is connected to a wire of the cover.

17. The imaging device of claim 13, wherein a light-receiving surface of the cover that is opposite to the light-transmitting surface of the cover is curved.

18. The imaging device of claim 13, wherein
the light-receiving surface of the imaging element has a first curvature in a first direction and a second curvature in a second direction orthogonal to the first direction, wherein the first curvature is different from the second curvature.

19. The imaging device of claim 13, wherein
the light-receiving surface of the imaging element has a first curvature in a first direction and no curvature in a second direction orthogonal to the first direction.

20. An imaging device comprising:
an imaging module;
a lens configured to focus light onto an imaging element of the imaging module; and
a retainer retaining the lens,
wherein the imaging module comprises:
the imaging element having a light-receiving surface configured to receive light and having an electrode pad at a periphery of the light-receiving surface;
a cover covering the light-receiving surface of the imaging element and having a wire connected to the electrode pad at a periphery of a light-transmitting surface of the cover that faces the light-receiving surface of the imaging element, and
an interposer substrate that has a space formed therein in which at least the light-receiving surface of the imaging element is arranged, and which is connected to the wire of the cover,
wherein the cover is curved such that the light-transmitting surface of the cover protrudes toward the imaging element, and
wherein the imaging element is stacked on the light-transmitting surface of the cover with an adhesive layer therebetween, and the light-receiving surface of the imaging element is concavely curved toward an opposite side of the imaging element that is opposite to the cover.
